(19) United States
(12) Patent Application Publication
(10) Pub. No.: US 2005/0057897 A1
(43) Pub. Date: Mar. 17, 2005

(54) Heat dissipating device with heat conductive posts

(76) Inventor: Hsiung Ming Shiu, Tau Yuan Hsien (TW)

Correspondence Address: Hsiung Ming Shiu, 235 Chung-Ho, Box 8-24, Taipei, TW

(21) Appl. No.: 10/662,399

(22) Filed: Sep. 16, 2003

(51) Int. Cl. H05K 7/20

(52) U.S. Cl. 361/688

(57) ABSTRACT

A heat dissipating device with heat conductive posts comprises a substrate made of aluminum; a lower portion of the substrate being formed with a plurality of via holes; a plurality of heat conductive posts made of copper. The heat conductive posts being embedded into the via holes of the substrate. A plurality of heat dissipating fins on one surface of the base. In manufacturing process, the substrate enters into a through hole of a shaping mold and then enters into a clip to be clamped by the clip so that the ribs on the surface of the heat conductive posts are embedded into inner walls of the via holes. Then, the whole substrate passes through the clip so be compressed by the clip. Thereby, the heat conductivity of the substrate is changed by embedding with the heat conductive posts.

### FIELD OF THE INVENTION

The present invention relates to heat dissipating device, and particularly to a heat dissipating device with heat conductive posts which has a higher heat conductivity and can be made quickly.

### BACKGROUND OF THE INVENTION

With the advance of technology, ICs and electronic elements are made more and more compact and have higher speed than old ones. Thereby, a great deal of heat is generated. However in current trend, it is desired that the electronic devices have compact size, that is, they are smaller, and thus, it is required that the heat dissipating devices of those devices are compact with a powerful heat dissipating ability.

Thus, current electronic devices need many high efficiency heating dissipating devices due to the operation speed increment of the electronic devices. In the prior art heating dissipating device, where a fin device with a plurality of heat dissipating sheets is locked to a fan and a bottom at two sides. The bottom plate is used to contact with the electronic device for dissipating heat. The heat dissipating capacity is confined by the number of the fins embedded in the bottom plate and thus the more the fins, the better the heat dissipating ability. Since the sizes of the electronic devices are made more and more compact, the heating dissipating devices must have higher efficiency for dissipating heat. Thereby, it is necessary to implant heat dissipating sheets into a bottom plate as many as possible. However, this is confined by the cutting steel sheets for forming grooves on the bottom plate. The width of the steel sheet is confined. If the steel sheet for cutting the bottom plate to form grooves is too narrow, the steel piece will break. Thereby, the conventional way has a limit in embedding heat dissipating sheets to the bottom plate and thus the heating dissipating ability is confined.

Moreover, the prior art is made of copper, which is expensive and heavy. The specific weight of copper is three times of that of aluminum and the price of the copper is about three times of that of aluminum.

Referring to FIGS. 1 and 2, the prior art heat dissipating device is illustrated. A heat dissipating device 6 is made of aluminum by extrusion. A lower side of the seat 60 of the heat dissipating device 6 has a plate 61 made of copper. A working table serves for fixing the heat dissipating device 6 and the seat 60. By high speed rotation base (not shown) to drive the plate 61 to rotate. When the plate 61 contacts and rubs the seat 60 of the heat dissipating device 6, heat will generate, and is used to melt the contact surfaces. The rotation base stops. Then an oil pressure rod (not shown) serves to press the base to be positioned. After cooling, the plate 61 is combined to a lower side of the heat dissipating device 6.

In above technology, the aluminum heat dissipating device 6 is combine with the copper plate 61, since the heat conductivity of the copper is 0.96 and the heat conductivity of the aluminum is 0.82. Thus the heat conductivity of copper is higher than aluminum. Thereby, when the plate 61 is adhered to an IC circuit, heat can be transferred to the heat dissipating device 6. Moreover, since the plate 61 has a larger contact area, since heat transfer quantity is Q=KAΔT/H, where K is heat transfer coefficient; A is the transfer area. ΔT is temperature difference; and H is a length. Therefore, it is apparent that the heat transfer quantity is positive proportional to the transfer area. Thereby, in one aspect, the plate 61 is transferred heat and in another aspect, larger area is between the heat dissipating device 6 and the plate 61 so as to have a preferred heat transfer efficiency. Thereby, above method can improve the defect of using copper which is expensive and heavy, but this prior art has the defect that more time is necessary to form a heat dissipating device since to combine the heat dissipating device 6 with the plate 61 needs the processes of positioning, high speed rotation, thermal melting, extrusion, resting, and cooling. Thereby, the yield ratio in the unit time is low. Thus the production of above mentioned prior art is not economic.

### SUMMARY OF THE INVENTION

Accordingly, the primary object of the present invention is to provide a heat dissipating device with heat conductive posts which comprises a substrate made of aluminum; a lower portion of the substrate being formed with a plurality of via holes; a plurality of heat conductive posts made of copper. The heat conductive posts being embedded into the via holes of the substrate. A plurality of heat dissipating fins on one surface of the base. In manufacturing process, the substrate enters into a through hole of a shaping mold and then enters into a clip to be clamped by the clip so that the ribs are embedded into inner walls of the via holes. Then, the substrate passes through the clip so be compressed by the clip. Thereby, the heat conductivity of the substrate is changed by embedding with the heat conductive posts. Moreover, each heat conductive post has formed with a plurality of ribs on an outer surface thereof.

The various objects and advantages of the present invention will be more readily understood from the following detailed description when read in conjunction with the appended drawing.

### BRIEF DESCRIPTION OF THE DRAWINGS

FIG. 1 is a schematic view of the prior art heat dissipating device.

FIG. 2 is an assembled perspective view of the prior art heat dissipating device.

FIG. 3 is an exploded perspective view of the substrate and heat conductive posts of the present invention.

FIG. 4 is a schematic view showing the shaping process of the present invention.

FIG. 5 is a cross sectional view about the shaping of the seat of the present invention.

FIG. 6 is a perspective view about the use of the present invention.

FIG. 7 is a schematic view showing the guiding of heat flow of the present invention.

FIG. 8 is an exploded perspective view of another embodiment of the present invention.

FIG. 9 is a cross sectional view showing the shaping of another embodiment of the present invention.

FIG. 10 is a schematic view showing the guiding of the heat flow in another embodiment of the present invention.

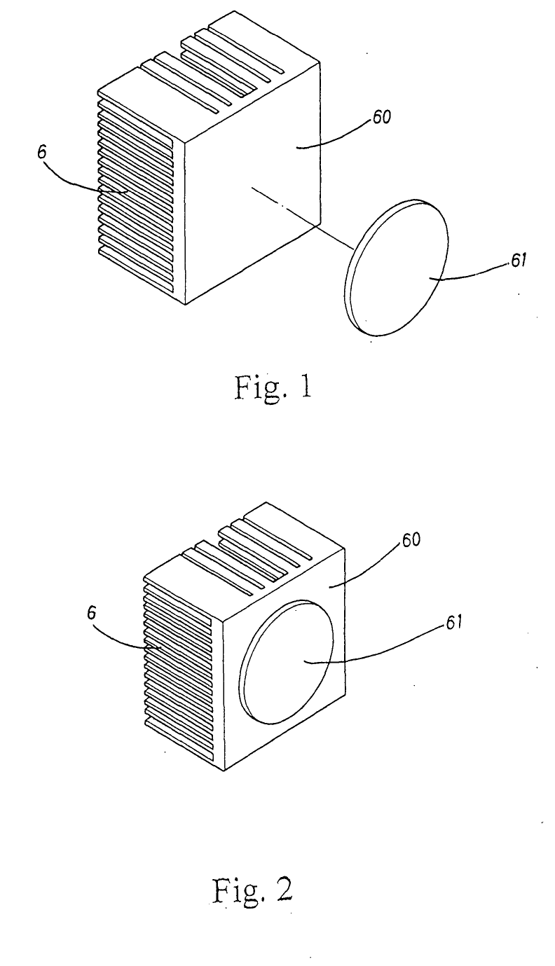

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

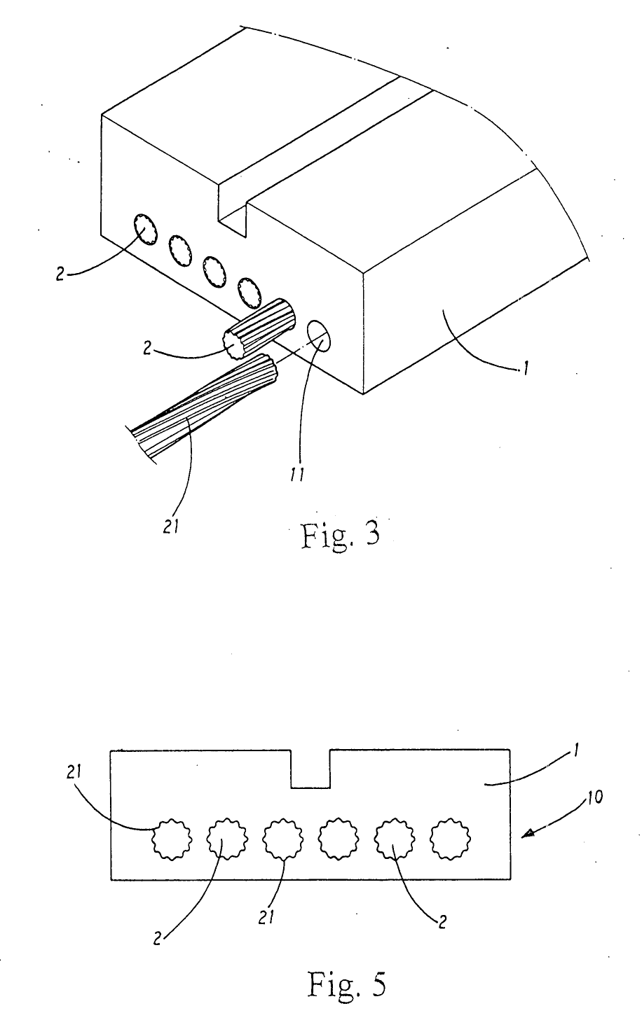

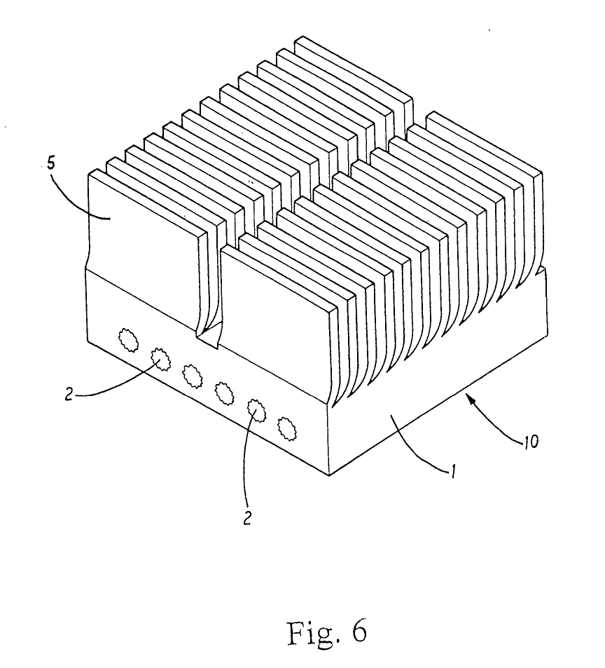

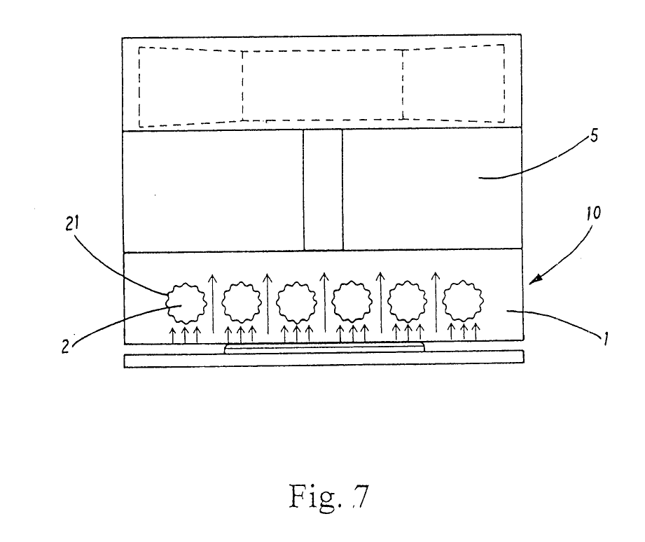

With reference to FIGS. 3 to 5, the present invention is illustrated. The present invention includes a substrate 1 made of aluminum which is light and can be machined easily. A lower portion of the substrate 1 is formed with a plurality of via holes 11. A plurality of heat conductive posts 2 made of copper which is a high conductivity material. Each heat conductive post 2 is formed with a plurality of ribs 21. The heat conductive posts 2 are axially embedded into the via holes 11 of the substrate 1. One end of substrate 1 is cut to have a reduced narrow portion 12. The substrate 1 enters into a through hole 30 of a shaping mold 3 and the narrow portion 12 protrudes from one opening of the through hole 30 and then enters into a clip 4 to be clamped by the clip 4 so that the ribs 21 are embedded into inner walls of the via holes 11. Then, the substrate 1 passes through the clip 4 so be compressed by the clip. Thereby, the heat conductivity of the substrate 1 is changed by embedding with the heat conductive posts 2. Thereby, when heat flows through the substrate 1, heat can be transferred out more rapidly. With reference to FIG. 7, the substrate 1 can be made as a seat 10. Then a plurality of heat dissipating fins 5 are formed on the seat 10 so as to further increase the heat dissipating capacity of the heat dissipating device.

Furthermore, in the present invention, the outer surface of each heat conductive post 2 is coated with tin glue (not shown). When, the heat conductive posts 2 are embedded into the substrate 1I The substrate 1 passes through the clip 4 and is compressed by the clip 4. In the clamping process by the clip 4, the tin glue on the heat conductive posts 2 will melt and then permeate into the walls of the via holes 11. Thereby, the heat conductive posts 2 and the substrate 1 can be combined tightly so as to have a preferred heat conductivity.

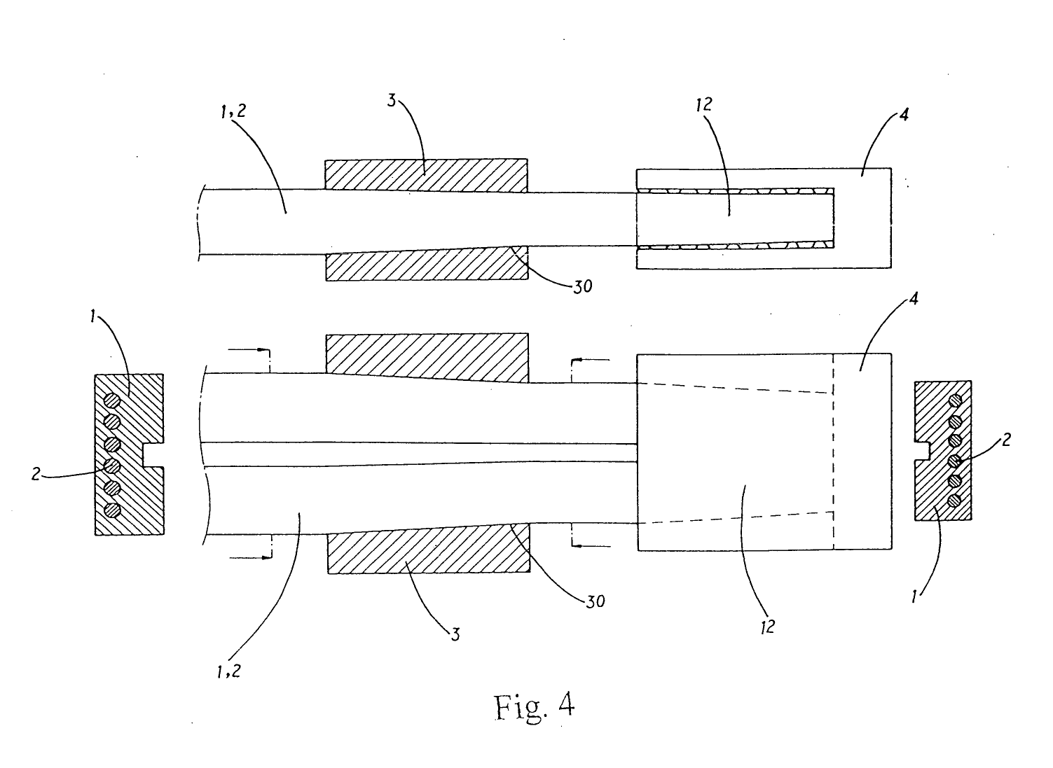

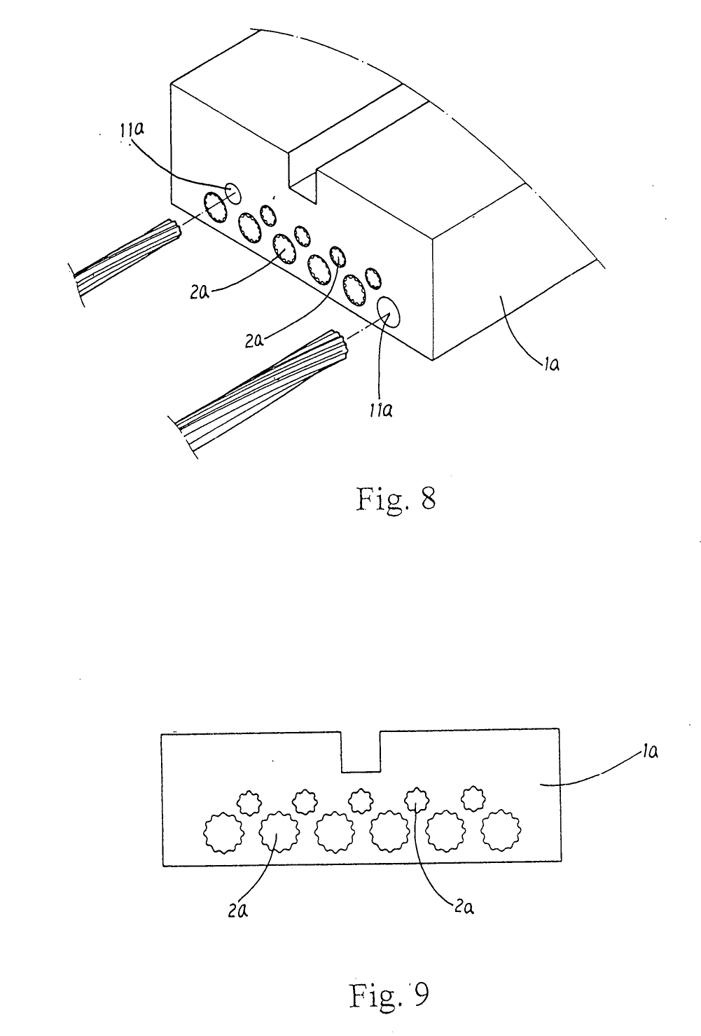

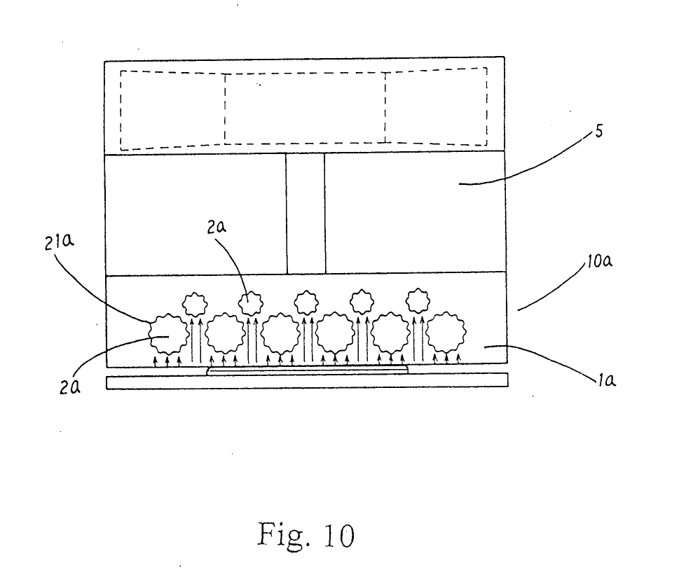

With reference to FIGS. 8 to 9, the exploded perspective view and cross sectional view of another embodiment of the present invention are illustrated. The lower portion of the substrate 1a is formed with a plurality of via holes 1a. The heat conductive posts 2a are exactly embedded into the via holes 11a to be tightly mounted therein. In this the present invention, the heat conductive posts may have different sizes. By the clip 4 to clamp the substrate 1a and the substrate 1a is guided into the shaping mold 3 (referring to FIG. 4), the substrate la is compressed and the via holes 11a of the substrate la are reduced inwards. Then the substrate 1 is cut to have a desired length to be as a seat 10a. Then heat dissipating fins 5 are mounted on a surface of the step seat 10a (referring to FIG. 10). Thereby, the substrate la may contain more heat conductive posts 2a and thus the substrate 1 has a preferred

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A heat dissipating device with heat conductive posts comprising:
a substrate; a lower portion of the substrate being formed with a plurality of via holes;
a plurality of heat conductive posts; the heat conductive posts being axially embedded into the via holes of the substrate; and
a plurality of heat dissipating fins on one surface of the base.

2. The heat dissipating device with heat conductive posts as claimed in claim 1, wherein in manufacturing process, one end of substrate is cut to have a reduced narrow portion; the substrate enters into a through hole of a shaping mold and the narrow portion protrudes from one opening of the through hole and then enters into a clip to be clamped by the clip so that surface of the heat conductive posts are tightly combined with inner walls of the via holes; then, the substrate passes through the clip so be compressed by the clip; thereby, the heat conductivity of the substrate is changed by embedding with the heat conductive posts.

3. The heat dissipating device with heat conductive posts as claimed in claim 2, wherein each heat conductive post has formed with a plurality of ribs on an outer surface thereof.

4. The heat dissipating device with heat conductive posts as claimed in claim 1, wherein the substrate is made of aluminum and the heat conductive posts are made of copper.

5. The heat dissipating device with heat conductive posts as claimed in claim 2, wherein the outer surface of each heat conductive post is coated with tin glue; in the compressing process by the clip, the tin glue will permeate into the walls of the via holes of the substrate; the heat conductive posts and the substrate is combined tightly so as to have a preferred heat conductivity.
